(19) United States
(12) Patent Application Publication
(10) Pub. No.: US 2007/0080680 A1
(43) Pub. Date: Apr. 12, 2007

(54) Apparatus, sensor, and method for measuring an amount of strain

(76) Inventors: Thaddeus Schroeder, Rochester Hills, MI (US); Bruno Lequesne, Troy, MI (US); Donald T. Morelli, White Lake, IL (US); Thomas A. Baudendistel, Farmersville, OH (US)

Correspondence Address: DELPHI TECHNOLOGIES, INC., M/C 480-410-202, PO BOX 5052, TROY, MI, 48007, US

(21) Appl. No.: 11/244,792

(22) Filed: Oct. 6, 2005

(51) Int. Cl. G01R 33/18

(52) U.S. Cl. 324/209

(57) ABSTRACT

An apparatus, sensor, and a method for measuring an applied strain are provided. The apparatus includes a strain sensor comprising an electrically conductive member composed of a magnetostrictive material. The apparatus further includes a signal generator electrically coupled to the electrically conductive member. The signal generator is configured to generate an electrical current that propagates through the electrically conductive member. The apparatus further includes a measuring circuit electrically coupled to the electrically conductive member. The measuring circuit is configured to measure at least one of an amount of inductance, resistance, and impedance of the electrically conductive member. The apparatus further includes a processor electrically coupled to the measuring circuit. The processor is configured to calculate the amount of force applied to the strain sensor based on at least one of the amount of inductance, resistance, and impedance of the electrically conductive member.

### TECHNICAL FIELD

The present application relates to an apparatus and a method for measuring an amount of strain.

### BACKGROUND

Strain sensors have been utilized to measure an applied force, torque, or pressure. One type of strain sensor includes a conductive wire that is wrapped around a separate core member of magnetostrictive material. Further, the strain sensor includes a ferromagnetic carrier that provides a return path for the magnetic flux outside of the wire oil. An air gap exists between the ferromagnetic carrier and the core member. An electrical current flowing through the wire coil generates a magnetic field that surrounds the wire and propagates partially within the core member. A strain applied to the core member changes the magnetic permeability therein. Inductance of the wire coil is a function of the permeability of the material through which the coil's magnetic field flows. Thus, the strain applied to the core member changes the inductance of the wire coil. A drawback with the strain sensor is that the air gap offers a permeability several orders of magnitude less than those of the ferromagnetic core or the ferromagnetic carrier, so even a very small air gap significantly increases the magnetic flux reluctance. As a result, the sensitivity of the strain sensor is reduced. Further, manufacturing tolerances affect the size of the air gap during manufacture of the strain sensors which result in inconsistent strain measurements by the sensors.

Accordingly, the inventors have recognized a need for a strain sensor that does not have an air gap.

### SUMMARY

An apparatus for measuring an applied force in accordance with an exemplary embodiment is provided. The apparatus includes a strain sensor comprising an electrically conductive member composed of a magnetostrictive material. The apparatus further includes a signal generator electrically coupled to the electrically conductive member. The signal generator is configured to generate an electrical current that propagates through the electrically conductive member. The apparatus further includes a measuring circuit electrically coupled to the electrically conductive member. The measuring circuit is configured to measure at least one of an amount of inductance, resistance, and impedance of the electrically conductive member. The apparatus further includes a processor electrically coupled to the measuring circuit. The processor is configured to calculate the amount of force applied to the strain sensor based on at least one of the amount of inductance, resistance, and impedance of the electrically conductive member.

A strain sensor in accordance with another exemplary embodiment is provided. The strain sensor includes an electrically conductive member comprising a magnetostrictive material. The electrically conductive member is configured to receive an applied force. The electrically conductive member has a change in impedance in response to the applied strain. The strain sensor further includes first and second covering members. The electrically conductive member is disposed between the first and second covering members. The second covering member has first and second apertures extending therethrough. The strain sensor further includes first and second electrical terminals disposed through the first and second apertures, respectively, of the second covering member that are coupled to the electrically conductive member.

A method for measuring an amount of force, utilizing a force measuring apparatus in accordance with another exemplary embodiment is provided. The apparatus comprises a strain sensor, a signal generator, a measuring circuit, and a processor. The strain sensor has an electrically conductive member comprising a magnetostrictive material. The signal generator is electrically coupled to the electrically conductive member. Further, the measuring circuit is electrically coupled to the electrically conductive member, and the processor is operably coupled to the measuring circuit. The method includes generating an electrical current utilizing the signal generator. The electrical current propagates through the electrically conductive member. The method further includes measuring at least one of an amount of inductance, resistance, and impedance of the electrically conductive member utilizing the measuring circuit receiving the electrical current. The method further includes calculating an amount of force being applied to the strain sensor based on at least one of the amount of inductance, resistance, and impedance utilizing the processor.

### BRIEF DESCRIPTION OF THE DRAWINGS

FIG. 1 is a block diagram of a strain measuring apparatus having a signal generator, a strain sensor, a measuring circuit, and a processor in accordance with an exemplary embodiment;

FIG. 2 is a top view of the strain sensor of FIG. 1 in accordance with an exemplary embodiment;

FIG. 3 is a cross-sectional view of the strain sensor of FIG. 1;

FIG. 4 is a cross-sectional view of an electrically conductive element of the strain sensor of FIG. 1 at a high current frequency;

FIG. 5 is a cross-sectional view of an electrically conductive element of the strain sensor of FIG. 1 at a low current frequency;

FIG. 6 is a flowchart of a method for measuring an amount of force;

FIG. 7 is a top view of a strain sensor in accordance with another exemplary embodiment;

FIG. 8 is a cross- sectional view of the strain sensor of FIG. 7; and

FIG. 9 is a cross-sectional view of a strain sensor in accordance with another exemplary embodiment.

### DETAILED DESCRIPTION OF EXEMPLARY EMBODIMENTS

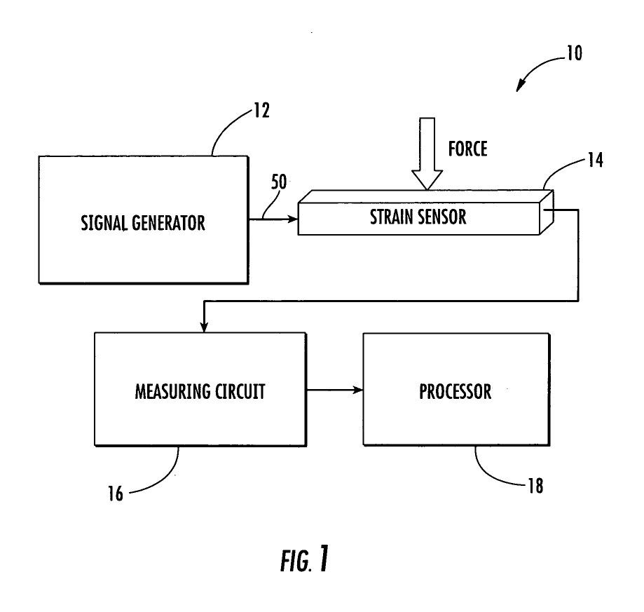

Referring to FIG. 1, an apparatus 10 for measuring a strain is illustrated. The apparatus 10 includes a signal generator 12, a strain sensor 14, a measuring circuit 16, and a processor 18.

The signal generator 12 is provided to generate an electrical current 50 that propagates through the strain sensor 14. In one embodiment, the electrical current 50 comprises a sinusoidal current having a predetermined frequency. The signal generator 12 is electrically coupled to strain sensor 14.

It should be noted that strain sensors disclosed herein measure an amount of strain applied to a material. These strain sensors are useful for the measurement of an amount of force, and amount of torque, and an amount of pressure, for example, which affect the strain level in a material. Typically, these strain sensor are named according to their application, such as a force sensor, a torque sensor, or a pressure sensor, for example. In the exemplary embodiments, the strain sensors are utilized to measure a force. However, in alternate embodiments, the strain sensors could be utilized to measure any physical quantity that can be determined from an applied strain to the strain sensor.

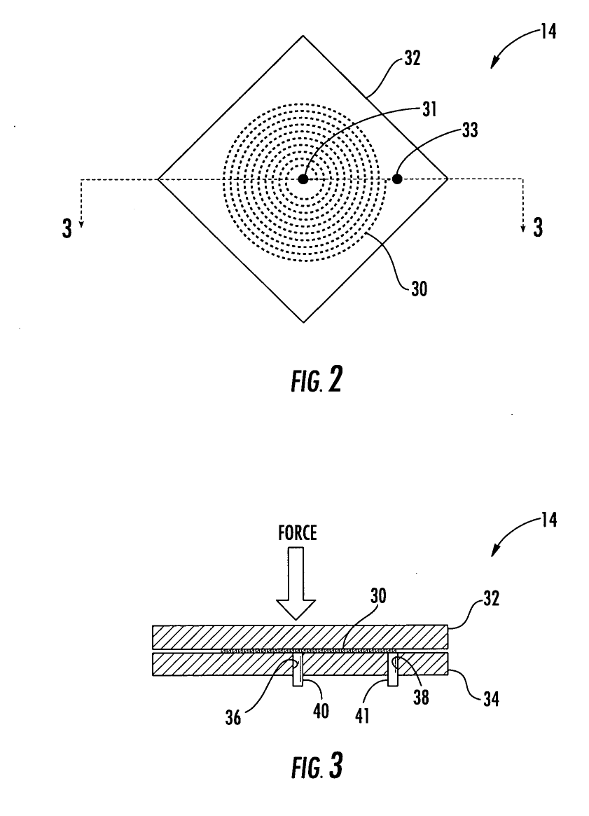

Referring to FIGS. 2 and 3, the strain sensor 14 is provided to detect a force applied to the strain sensor 14. The strain sensor 14 includes an electrically conductive member 30, optional covering members 32, 34, and electrical terminals 40, 41. The electrically conductive member 30 is constructed from a magnetostrictive material. Non-limiting examples of a magnetostrictive material include one or more of: cobalt, iron, nickel, rare-earth elements having magnetostrictive properties, and alloys thereof. In one embodiment, the electrically conductive member 30 is a magnetostrictive wire. Of course, in alternate embodiments, the electrically conductive member 30 can be formed in a plurality of different shapes and dimensions. For example, the electrically conductive element can comprise a plate member or a bar member or a beam-shaped member. Further, for example, the electrically conductive member element can comprise an electrical trace disposed on a substrate. As shown, the electrically conductive member 30 is a generally spiral-shaped planar wire that extends from a node 31 to a node 33. The terminals 40, 41 extend through apertures 36, 38 of the covering member 34 and are electrically coupled to the nodes 31, 33, respectively. Further, the terminals 40 and 41 are electrically coupled to the signal generator 12 and to the measuring circuit 16.

Referring to FIG. 3, in one embodiment, a force induces a strain to member 30 in a direction substantially perpendicular to a direction of the electrical current flowing through the member 30. In an alternate embodiment, if the covering member 34 were removed from the strain sensor 14, the force would induce a strain in a direction that would tend to stretch the member 30. In this event, the strain would be generally in a direction similar to the direction of the electrical current flowing through the member 30. It should be noted that depending on the application of strain sensor 14 and on the design of sensor 14 including the material utilized for member 30, the strain may be in-line, perpendicular, or at any angle with respect to a direction of the electrical current flowing through the member 30.

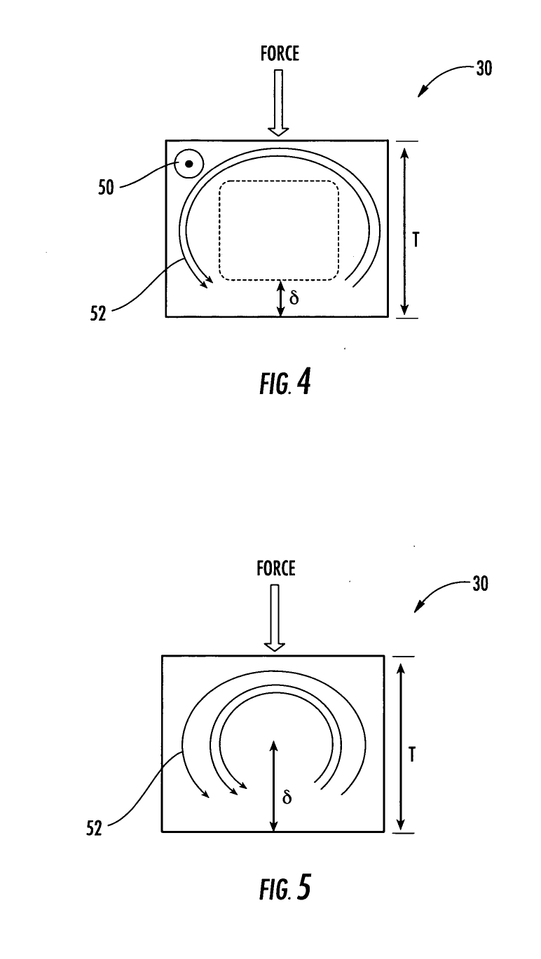

Referring to FIGS. 4 and 5, the electrically conductive member 30 has a rectangular cross-sectional configuration or shape. It is of course understood that electrically conductive member 30 may comprise other cross-sectional configurations, including an oval configuration, a round configuration, or other shapes known to those skilled in the art. In order to make use of member 30 as a strain sensor, the electrical current 50 supplied by signal generator 12 flows through the member 30, which in turn creates a magnetic field 52 around the member 30 in a path transverse to the current flow. In an exemplary embodiment utilizing an electrically conductive, magnetostrictive element having a square cross-section configuration, the magnetic field has a maximum value inside of the member 30. At low current frequencies, an inductance L of the member 30 varies in direct proportion to the permeability μ of the member 30, according to the equation:

$$L = μ \frac{Λ ( T / 2 )}{P} ,$$

where ,μ is the permeability, Λ is the length, T is the thickness, and P is the perimeter of the electrically conductive, magnetostrictive member 30. As force is applied to the member 30, its magnetic permeability μ changes, thus effecting inductance L. At higher frequencies, because of skin effects, inductance L changes in direct proportion to the square root of μ, according to the equation:

$$L \approx \frac{\sqrt{ρμ} Λ}{\sqrt{π f} P} ,$$

where p is the resistivity of the electrically conductive, magnetostrictive member 30, and f is the frequency of electrical current 50. The approximate line of separation dividing low and high frequency occurs when the skin depth δ, corresponding to a depth from an exterior of the member 30 to a region inside the member 30 that is void of current and of magnetic flux, equals half the thickness T of the member 30, according to the equation:

$$δ = \frac{T}{2} = \sqrt{\frac{ρ}{π f μ}} .$$

At higher frequencies and because of skin effects, the effective resistance of the electrically conductive, magnetostrictive member 30 is also a function of permeability. Thus, an amount of inductance, an amount of resistance, or an amount of impedance are each indicative of an amount of strain applied to the member 30.

Referring to FIGS. 2 and 3, the covering members 32, 34 comprise plate members that are disposed on opposite sides of the electrically conductive member 30. The covering members 32, 34 are constructed from a ceramic or a plastic material. Further, the covering members 32, 34 are fixedly coupled to one another with an adhesive or an epoxy. Of course, in alternate embodiments, other coupling means could be utilized to couple the covering members 32, 34 to one another. The covering members 32, 34 are configured to receive an applied force and to deliver the applied force to the electrically conductive, magnetostrictive member 30.

In an alternate embodiment of the electrically conductive member 30, an insulative sheath covering can be disposed around the electrically conductive member 30.

Referring to FIG. 1, the measuring circuit 16 is provided to measure at least one of an amount of inductance, an amount of resistance, or an amount of impedance in electrically conductive member 30. In one exemplary embodiment, the measuring circuit 16 outputs a signal indicative of the inductance level of the member 30. In another exemplary embodiment, the measuring circuit 16 outputs a signal indicative of a resistance level of the member 30. In another exemplary embodiment, the measuring circuit 16 outputs a signal indicative of an impedance level of the member 30. In other embodiments, the measuring circuit 16 can provide a multi-bit digital representation of an analog signal indicating at least one of an inductance level a resistance level, and an impedance level of the member 30. The measuring circuit 16 is electrically coupled to the strain sensor 14 and to the processor 18.

The processor 18 is provided for calculating an amount of force applied to the strain sensor 14 based on the output signal from the measuring circuit 16. The processor 18 is electrically coupled to the measuring circuit 16 and receives an output signal, indicative of at least one of an amount of inductance, an amount of resistance, or an amount of impedance of the strain sensor 14, from the measuring circuit 16. In one embodiment, the processor 18 comprises a computer that receives an output signal indicative of an impedance value of the strain sensor 14 and calculates an amount of force according to a metric unit such as Newtons (kg·m·S⁻² ). Of course, in other embodiments, the processor 18 can comprise other computational units such as a microprocessor, a programmable gate array, an ASIC, or the like.

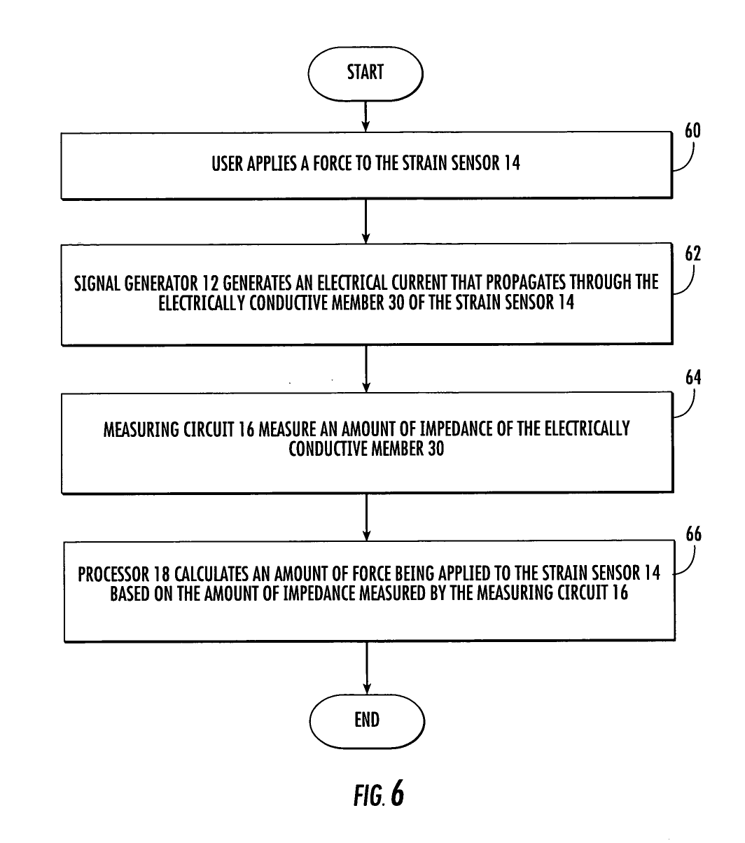

Referring now to FIGS. 1 and 6, a method for measuring an amount of force using the force measuring apparatus 10 will be explained. The method will determine the amount of force based on an impedance level of the strain sensor 14.

At step 60, a user applies a force to the strain sensor 14.

Next at step 62, the signal generator 12 generates an electrical current that propagates through the electrically conductive member 30 of the strain sensor 14.

Next at step 64, the measuring circuit 16 measures an amount of impedance of the electrically conductive member 30.

Next at step 66, the processor 18 calculates an amount of force being applied to the strain sensor 14 based on the amount of impedance measured by the measuring circuit 16. After step 66, the method is exited.

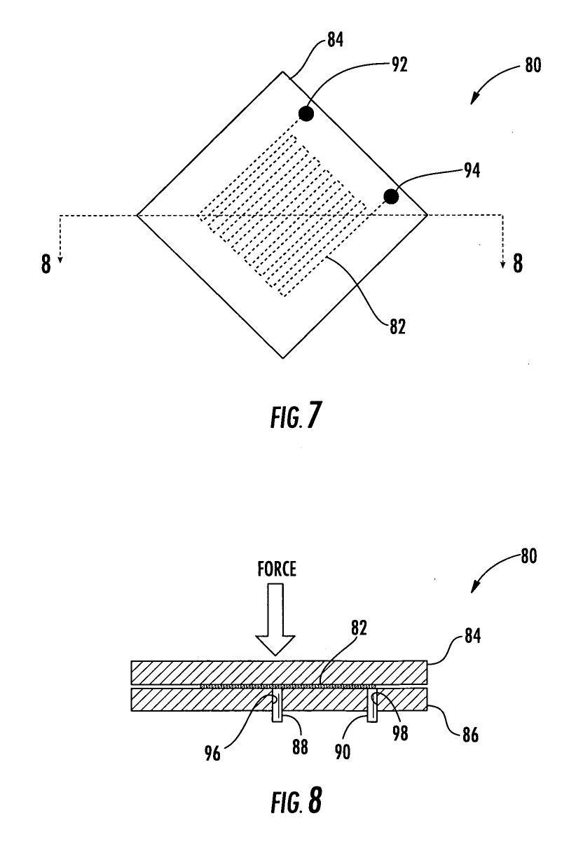

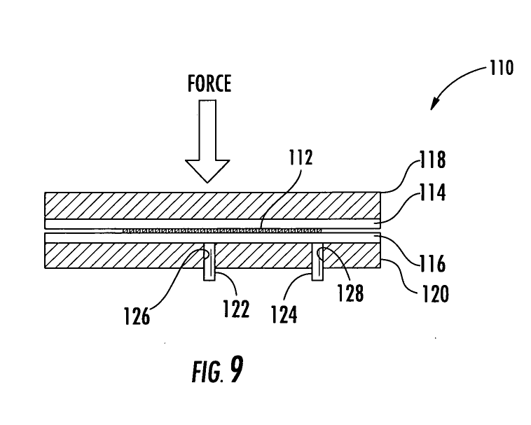

Referring to FIGS. 7 and 8, a strain sensor 80 for detecting a force applied to the strain sensor 80 in accordance with another exemplary embodiment is provided. The strain sensor 80 can be utilized instead of the strain sensor 14 in the system 10. The strain sensor 80 comprises an electrically conductive wire 82, optional covering members 84, 86, and electrical terminals 88, 90. In particular, the electrically conductive wire 82 comprises a magnetostrictive wire extending in a generally serpentine shape. Further, the electrically conductive wire 82 is electrically coupled to nodes 92, 94. The terminals 88, 90 extend through apertures 96, 98, respectively, of the covering member 86 and are electrically coupled to the nodes 92, 94, respectively. The terminals 88 and 90 are electrically coupled to the signal generator 12 and to the measuring circuit 16. The electrically conductive wire 82 of the strain sensor 80 has an impedance value indicative of the force applied to the strain sensor 80. Thus, the strain sensor 80 operates in a manner similar to the strain sensor 14 as described above.

Referring to FIG. 9, a strain sensor 110 for detecting a force applied to the strain sensor 110 in accordance with another exemplary embodiment is provided. The strain sensor 110 can be utilized instead of the strain sensor 14 in the system 10. The strain sensor 110 comprises an electrically conductive wire 112, insulative layers 114, 116, covering members 118, 120, and electrical terminals 122, 124.

The electrically conductive wire 112 comprises a magnetostrictive wire extending in a generally spiral shape. Of course, the wire 112 could extend in other shapes known to those skilled in the art.

In one exemplary embodiment, the covering members 118, 120 are metallic and therefore electrically conductive. The insulative layers 114, 116 prevent the electric current 50 from propagating in the covering members 118, 120. The insulative layers 114, 116 are disposed on opposite sides of the electrically conductive wire 112 and may be coupled together utilizing an adhesive. In one embodiment, the insulative layers 114, 116 comprise plastic layers. Of course, in alternate embodiments, other types of insulative layers could be utilized such as paper layers, or air layers, for example.

The covering member 118 is fixedly coupled on a side of the insulative layer 114 opposite the wire 112. The covering member 120 is fixedly coupled on a side of the insulative layer 116 opposite the wire 112. Both of apertures 126, 128 extend through the insulative layer 116 and the covering member 120.

The terminals 122, 124 extend through apertures 126, 128, respectively, and are electrically coupled to the electrically conductive wire 112. The terminals 122 and 124 are electrically coupled to the signal generator 12 and the terminal 124 is electrically coupled to the measuring circuit 16. The electrically conductive wire 112 of the strain sensor 110 has an impedance level indicative of an amount of force being applied to the strain sensor 110. Thus, the strain sensor 110 operates in a manner similar to the strain sensor 14 as described above.

The apparatus and the method for measuring an applied force provide a substantial advantage over other systems and methods. In particular, the apparatus and method have a technical effect of using an electrically conductive member to detect an amount of force being applied to a strain sensor, instead of utilizing a separate core member, conductors, and ferromagnetic carries having an associated air gap therebetween. As a result, the inventive apparatus and method have increased sensitivity for measuring forces and provide more consistent force measurements since manufacturing tolerances associated with the air gap are eliminated.

The terms “first,” “second,” and the like, herein do not denote any order, quantity, or importance, but rather are used to distinguish one element from another, and the terms “a” and “an” herein do not denote a limitation of quantity, but rather denote the presence of at least one of the referenced item. Unless defined otherwise, technical and scientific terms used herein have the same meaning as is commonly understood by one of skill in the art to which this invention belongs.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

1. An appartus for measuring an applied strain, comprising:
a strain sensor comprising an electrically conductive member composed of a magnetostrictive material;
a signal generator electrically coupled to the electrically conductive member, the signal generator configured to generate an electrical current that propagates through the electrically conductive member;
a first circuit electrically coupled to the electrically conductive member, the first circuit configured to measure at least one of an amount of inductance, resistance, and impedance of the electrically conductive member utilizing the electrical current; and
a processor electrically coupled to the first circuit, the processor configured to calculate an amount of strain being applied to the strain sensor on at least one of the amount of inductance, resistance, and impedance of the electrically conductive member.

2. The appartus of claim 1, wherein the magnetostrictive material comprises nickel, iron, or a nickel-iron alloy.

3. The appartus of claim 1, wherein the strain sensor further comprises first and second covering members, the electrically conductive member being disposed between the first and second covering members.

4. The appartus of claim 3, wherein the second covering member has first and second apertures extending therethrough, the strain sensor further including first and second electrical terminals disposed through the first and second apertures, respectively, and electrically coupled to the electrically conductive member.

5. The apparatus of claim 4, wherein the electrically conductive member comprises a spiral-shaped wire having first and second ends, the first end operably coupled to the first electrical terminal, at least the first being electrically coupled to the signal generator, at least the second being electrically coupled to the first circuit.

6. The appartus of claim 3, wherein the electrically conductive member forms a serpentine-shaped wire having first and second ends, at least the first end being operably coupled to the signal generator, and at least the second end being electrically coupled to the first circuit.

7. The apparatus of claim 3, further comprising first and second electrically insulative layers disposed, respectively between the electrically conductive member and the first and second covering members, each of the first and second covering members comprising a conducting, non-ferromagnetic material.

8. The apparatus of claim 3, further comprising a non-ferromagnetic layer disposed between the electrically conductive member and each of the first and second covering members, each of the first and second covering members comprising a ferromagnetic material.

9. (canceled)

10. The apparatus of claim 1, further comprising an outer covering surrounding the electrically conductive member.

11. The apparatus of claim 10, further comprising an electrically insulative layer disposed between the outer covering and the electrically conductive member.

12. The appartus of claim 11, wherein the electrically insulative layer comprises at least one of an air layer, a plastic layer, a paper layer.

13. The appartus of claim 10, wherein the outer covering comprises an electrically conductive, non-ferromagnetic material.

14. The appartus of claim 1, wherein the electrically conductive member is a wire comprised of a magnetostrictive material, the wire having a generally rectangular cross-sectional area.

15. (canceled)

16. A method for measuring an amount of strain utilizing a strain measuring appartus, the apparatus comprising a strain sensor, a signal generator, a first circuit, and a processor, the strain sensor having an electrically conductive member comprising a magnetostrictive material, the signal generator electrically coupled to the electrically conductive member, the first circuit electrically coupled to the electrically conductive member, and the processor operably coupled to the first circuit, the method comprising:
generating an electrical current utilizing the signal generator, the electrical current propagating through the electrically conductive member;
measuring at least one of an amount of inductance, resistance, and impedance of the electrically conductive member utilizing the first circuit receiving the electrical current; and
calculating a value indicating an amount of strain being applied to the strain sensor based on at least one of the amount of inductance, resistance, and impedance utilizing the processor.

17. The method of claim 16, wherein the strain applied to the strain sensor is applied in a direction generally perpendicular to a direction of the electrical current propagating through the electrically conductive member.
